(19) United States
(12) Patent Application Publication
(10) Pub. No.: US 2008/0135210 A1
(43) Pub. Date: Jun. 12, 2008

(54) HEAT DISSIPATION MODULE

(75) Inventors: Frank Wang, Taoyuan County (TW); Chih-Kai Yang, Taipei County (TW)

Correspondence Address: J C PATENTS, INC., 4 VENTURE, SUITE 250, IRVINE, CA, 92618, US

(73) Assignee: INVENTEC CORPORATION, Taipei City (TW)

(21) Appl. No.: 11/675,844

(22) Filed: Feb. 16, 2007

(30) Foreign Application Priority Data
Dec. 8, 2006 (TW) 95145971

(51) Int. Cl. F28F 1/00; H05K 7/20

(52) U.S. Cl. 165/80.3; 165/121; 165/104.33; 361/697

(57) ABSTRACT

A heat dissipation module including a housing, a fan module, a cooling fin set, and a heat pipe is provided. The housing has a fan accommodation area, a first heat dissipation area, a second heat dissipation area, and a heat conducting area. The fan module is disposed in the fan accommodation area, and the cooling fin set is disposed in the first heat dissipation area. The heat pipe has a heat absorbing portion, a curved portion, and a heat dissipation portion, and the curved portion connects the heat absorbing portion and the heat dissipation portion. The curved portion is in thermal contact with the second dissipation area, and the heat dissipation portion is in thermal contact with the cooling fin set. Thus, the efficiency of heat dissipation of the heat pipe is improved.

### CROSS-REFERENCE TO RELATED APPLICATION

This application claims the priority benefit of Taiwan application serial no. 95145971, filed Dec. 8, 2006. All disclosure of the Taiwan application is incorporated herein by reference.

### BACKGROUND OF THE INVENTION

1. Field of the Invention

The present invention relates to a heat dissipation module. More particularly, the present invention relates to a heat dissipation module applicable to electronic devices.

2. Description of Related Art

In recent years, electronic devices are designed smaller and multi-functional, and the more powerful electronic devices require chips of higher speed. However, as the chips with higher speed generate more heat, and the electronic devices are miniaturized, heat dissipation modules have become an indispensable element in the electronic devices.

FIG. 1 is a schematic stereogram of a conventional heat dissipation module. Referring to FIG. 1, the conventional heat dissipation module 100 includes a heat pipe 110, cooling fins 120, and a fan 130. The heat pipe 110 has a heat dissipation portion 112, a heat absorbing portion 114, and a curved portion 116. The heat absorbing portion 114 is in thermal contact with a heat-generating element 50, and transmits heat produced by the heat-generating element 50 to the heat dissipation portion 112 via the curved portion 116. The cooling fins 120 are in the shape of a cuboid, and is in thermal contact with the heat dissipation portion 112 of the heat pipe 110. The air flow produced by the fan 130 passes through the cooling fins 120, so as to dissipate the waste heat into the air.

However, as electronic devices are designed smaller and multi-functional, the electronic devices have no more space for accommodating larger heat dissipation modules. When the heat-generating element generates more heat, the capacity of heat dissipation of the conventional heat dissipation module is not enough. In addition, limited by the shapes of the cooling fins and the fan, the fan cannot dissipate the heat of the curved portion of the heat pipe, and thus the heat dissipation capacity of the heat dissipation module is influenced.

### SUMMARY OF THE INVENTION

The present invention is directed to provide a heat dissipation module, so as to alleviate the disadvantage that a fan cannot dissipate heat of a curved portion of a heat pipe.

As embodied and broadly described herein, the present invention provides a heat dissipation module, which comprises a housing, a fan module, a cooling fin set, and a heat pipe. The housing comprises a fan accommodation area, a first heat dissipation area, a second heat dissipation area, and a heat conducting area. The fan accommodation area is communicated with the first heat dissipation area and the second heat dissipation area. The fan module is disposed in the fan accommodation area. The cooling fin set is disposed in the first heat dissipation area. The heat pipe has a heat absorbing portion, a curved portion, and a heat dissipation portion, and the curved portion connects the heat absorbing portion and the heat dissipation portion. The curved portion is in thermal contact with the second dissipation area, and the heat dissipation portion is in thermal contact with the cooling fin set.

In one embodiment of the present invention, the second heat dissipation area has a rib set.

In one embodiment of the present invention, the housing is fabricated by means of die casting.

The heat dissipation module of the present invention has the second heat dissipation area in thermal contact with the curved portion of the heat pipe, and the air flow produced by the fan module passes through the second heat dissipation area. Therefore, compared with the conventional art, the heat of the heat dissipation portion of the heat pipe can be dissipated by the cooling fin set, and the curved portion also has fine heat dissipation effect. Thus, the use efficiency of the heat pipe is improved, and the heat dissipation module can maintain the same heat dissipation capacity with a shorter heat pipe. Accordingly, the volume of the heat dissipation module is reduced.

In order to make the aforementioned features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic stereogram of a conventional heat dissipation module.

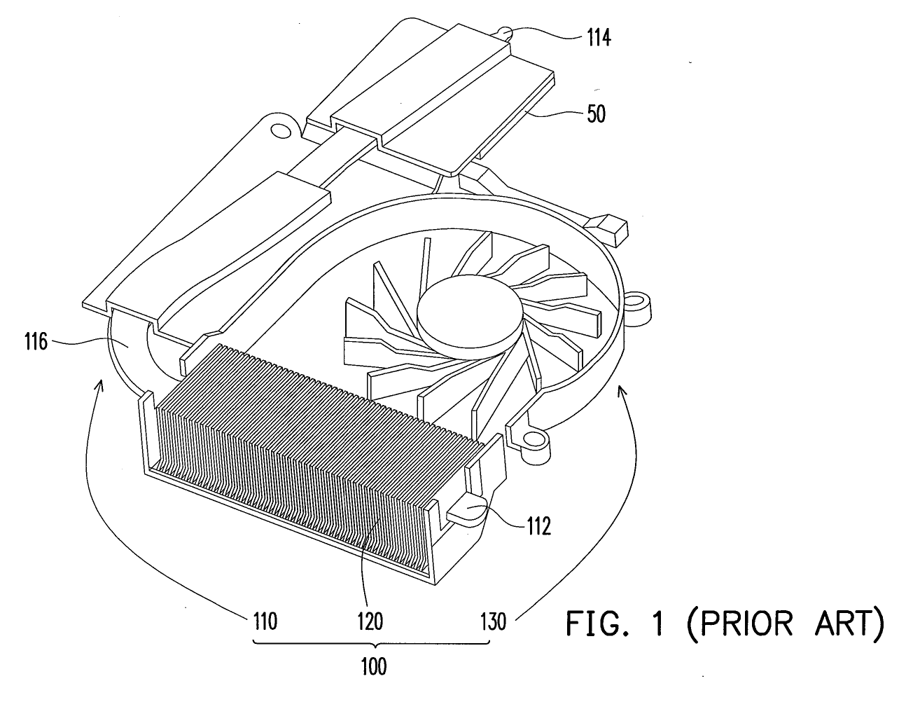

FIG. 2 is a top view of the heat dissipation module of the present invention.

FIG. 3 is a stereogram of the heat dissipation module of FIG. 2 applied to a heat-generating element.

### DESCRIPTION OF EMBODIMENTS

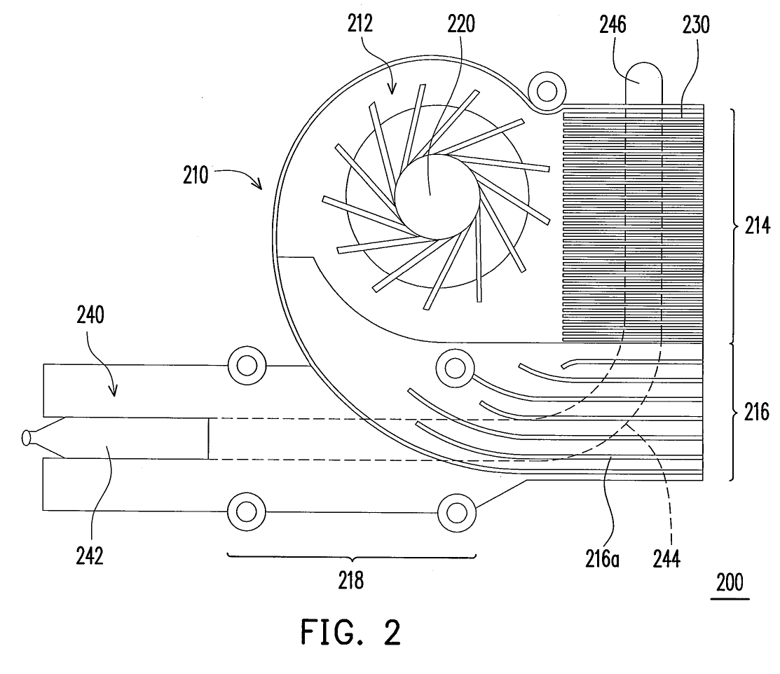

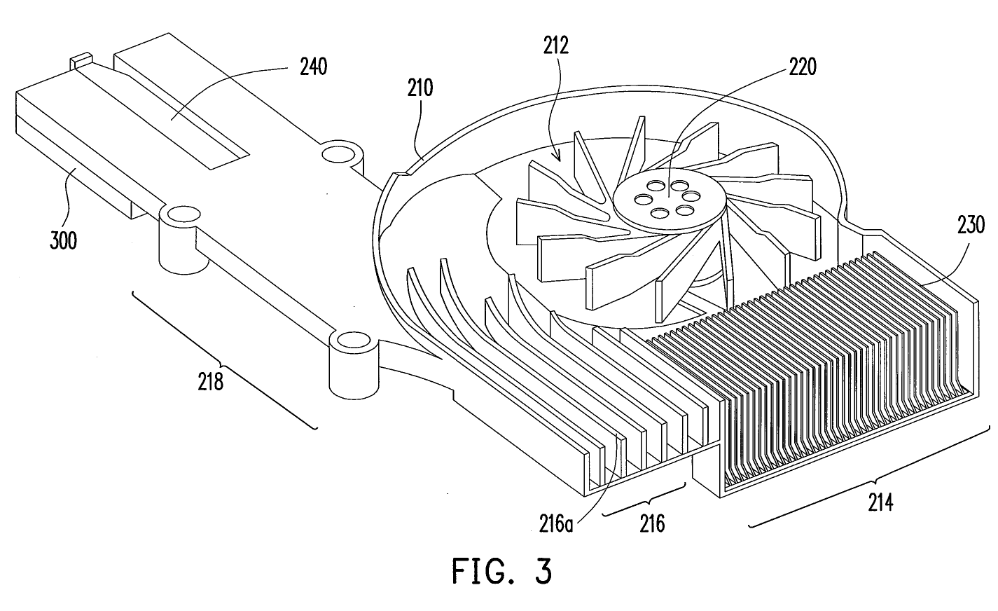

FIG. 2 is a top view of the heat dissipation module of the present invention, and FIG. 3 is a stereogram of the heat dissipation module of FIG. 2 applied to a heat-generating element. Referring to FIGS. 2 and 3, the heat dissipation module 200 includes a housing 210, a fan module 220, a cooling fin set 230, and a heat pipe 240. The housing 210, for example, is fabricated by means of die casting, and the material of the housing 210 is a material of high thermal conductivity coefficient, for example, metal such as copper or aluminum, so as to enhance the heat dissipation effect of the heat dissipation module 200.

In addition, the housing 210 has a fan accommodation area 212, a first heat dissipation area 214, a second heat dissipation area 216, and a heat conducting area 218. The fan module 220 is disposed in the fan blade accommodation area 212, and the cooling fin set 230 is disposed in the first heat dissipation area 214. The second heat dissipation area 216 can have a rib set 216a, which is arranged at an air outlet of the fan module 220 in a same direction of the cooling fin set 230, so as to increase the area of the second heat dissipation area 216 in contact with air, thereby enhancing the heat dissipation effect of the second heat dissipation area 216.

The heat pipe 240 is L-shaped, and has a heat absorbing portion 242, a curved portion 244, and a heat dissipation portion 246. The heat pipe 240 passes through the heat-generating element 300, the heat conducting 218, the second heat dissipation area 216, and the first heat dissipation area 214 sequentially. The heat absorbing portion 242 is in thermal contact with the heat-generating element 300, the curved portion 244 is in thermal contact with the second heat dissipation area 216, and the heat dissipation portion 246 is in thermal contact with the cooling fin set 230.

The heat-generating element 300, for example, is a CPU(central processing unit), a graphic chip, or a digital signal processor. The heat plate 240 transmits the heat produced by the heat-generating element 300 to the rib set 216a of the second heat dissipation area 216 and the cooling fin set 230 in the first heat dissipation area 214 via the heat-conducting area 218. The fan accommodation area 212 is communicated with the first dissipation area 214 and the second heat dissipation area 216, so the air flow generated when the fan module 220 rotates can pass through the first heat dissipation area 214 and the second heat dissipation area 216, and takes out the heat from the rib set 216a and the cooling fin set 230. Thus, the heat dissipation is realized.

The heat dissipation module 200 of this embodiment has the second heat dissipation area 216 in thermal contact with the curved portion 244 of the heat pipe 240, and the air flow produced by the fan module 220 can pass through the second heat dissipation area 216. Therefore, compared with the conventional art, the heat of the heat dissipation portion 246 of the heat pipe 240 can be dissipated by the cooling fin set 230, and the curved portion 244 also has fine heat dissipation effect. Thus, the use efficiency of the heat pipe 240 is improved, and the heat dissipation capacity of the heat dissipation module 220 increases with the increase of the heat dissipation capacity of the heat pipe 240.

To sum up, the heat dissipation module of the present invention has a second heat dissipation area. The second heat dissipation area is in thermal contact with the curved portion of the heat pipe, and the air flow produced by the fan module passes through the second heat dissipation area. Compared with the conventional art, the heat pipe of the heat dissipation module of the present invention not only dissipates heat with the cooling fin set at the heat dissipation portion, but also includes the rib set at the curved portion, in which the fan module generates the air flow to improve the heat dissipation.

It will be apparent to persons of ordinary art in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat dissipation module, comprising:
a housing, comprising a fan accommodation area, a first heat dissipation area, a second heat dissipation area, and a heat conducting area, wherein the fan accommodation area is communicated with the first heat dissipation area and the second heat dissipation area;
a fan module, disposed in the fan accommodation area;
a cooling fin set, disposed in the first heat dissipation area; and
a heat pipe, comprising a heat absorbing portion, a curved portion, and a heat dissipation portion, wherein the curved portion connects the heat absorbing portion and the heat dissipation portion, the curved portion is in thermal contact with the second dissipation area, and the heat dissipation portion is in thermal contact with the cooling fin set.

2. The heat dissipation module as claimed in claim 1, wherein the second heat dissipation area comprises a rib set.

3. The heat dissipation module as claimed in claim 1, wherein the housing is fabricated by means of die casting.

4. The heat dissipation module as claimed in claim 1, wherein the housing is made of a metal.
